(19) United States
(12) Patent Application Publication
(10) Pub. No.: US 2012/0208376 A1
(43) Pub. Date: Aug. 16, 2012

(54) METHOD OF FORMING SILICON NITRIDE FILM AND METHOD OF MANUFACTURING SEMICONDUCTOR MEMORY DEVICE

(75) Inventors: Minoru Honda, Nirasaki City (JP); Masayuki Kohno, Nirasaki City (JP); Toshio Nakanishi, Nirasaki City (JP)

(73) Assignee: TOKYO ELECTRON LIMITED, Tokyo (JP)

(21) Appl. No.: 13/499,445

(22) PCT Filed: Sep. 28, 2010
(86) PCT No.: PCT/JP2010/066797

§ 371 Date: May 2, 2012

(30) Foreign Application Priority Data
Sep. 30, 2009 (JP) 2009-227640

(51) Int. Cl. H01L 21/318

(52) U.S. Cl. 438/791; 257/E21.293

(57) ABSTRACT

A method of forming a silicon nitride film by using a plasma CVD method, where the silicon nitride film has abundant traps and is useful as a charge accumulation layer of a nonvolatile semiconductor memory device. A silicon nitride film having a lot of traps is formed by performing plasma CVD by using processing gases including a nitrogen gas and a gas of a compound formed of silicon atoms and chlorine atoms, and by setting a pressure in a processing container within a range between more than or equal to 0.1 Pa and less than or equal to 8 Pa, in a plasma CVD apparatus that performs film-formation by introducing microwaves in the processing container by using a planar antenna having a plurality of holes to generate plasma.

### TECHNICAL FIELD

The present invention relates to a method of forming a silicon nitride film and a method of manufacturing a semiconductor memory device.

### BACKGROUND ART

Current nonvolatile semiconductor memory devices represented by an electrically erasable and programmable read only memory (EEPROM) capable of an electrical rewriting operation, or the like, have a stacked structure called a silicon-oxide-nitride-oxide-silicon (SONOS) type or a metal-oxide-nitride-oxide-silicon (MONOS) type. According to a semiconductor memory device in such a type, at least one layer of a silicon nitride film (nitride) interposed between silicon dioxide films (oxide) is used as a charge accumulation region to hold information. In other words, in the nonvolatile semiconductor memory device, a voltage is applied between a semiconductor substrate (silicon) and a control gate electrode (silicon or metal) so as to preserve data by injecting electrons into the silicon nitride film of the charge accumulation region or remove electrons accumulated in the silicon nitride film, thereby performing rewriting, i.e., preserving and erasing of data. In the nonvolatile semiconductor memory device, a data writing characteristic is related to easy injection of electrons to the silicon nitride film constituting the charge accumulation region, and a data holding characteristic is related to easy detachment of electrons from the silicon nitride film, specifically related to a charge trapping center (trap) existing in the silicon nitride film.

Patent Document 1 discloses providing of a transition layer containing a lot of silicon (Si) at center portions of a silicon nitride film and a top oxide film as a technology about nonvolatile semiconductor memory devices, so as to increase a trap density of an interface between the silicon nitride film and the top oxide film.

Accompanied by recent high integration of a semiconductor device, an element structure of a nonvolatile semiconductor memory device has been rapidly miniaturized. In order to miniaturize nonvolatile semiconductor memory devices, a data writing performance needs to be increased by increasing a trap of a silicon nitride film constituting a charge accumulation layer, with respect to each nonvolatile semiconductor memory device.

However, it is technically difficult to control a trap formation in a silicon nitride film while forming the silicon nitride film via a film-forming method using a low pressure chemical vapor deposition (CVD) method or a thermal CVD method. In a plasma CVD method, it may be thought that many traps can be formed in a silicon nitride film by reinforcing ionicity of plasma by setting a process pressure in a processing container to a high vacuum state (for example, less than or equal to 3 Pa), but in order to maintain an inside of the processing container in the high vacuum state, an apparatus load is increased, for example, a high performance exhaust apparatus is required, a vacuum seal technology that can endure a high vacuum state is required, and a pressure-resistant container is required, and thus expenses are also increased. Also in the high vacuum state, since plasma energy is increased, a sputtering effect on an element or the like in the processing container is increased, and thus problems may be generated in terms of processes, for example, a contamination danger may increase due to particles or the like, the formed silicon nitride film may be damaged, or a step coverage with respect to film-formation may deteriorate.

[Patent Document 1] Japanese Laid-Open Patent Publication No. hei 5-145078 (for example, paragraph [0015], etc.)

### DISCLOSURE OF THE INVENTION

### Technical Problem

To solve the above and/or other problems, the present invention provides a method of forming a silicon nitride film by using a plasma CVD method, where the silicon nitride film includes abundant traps and is useful as a charge accumulation layer of a nonvolatile semiconductor memory device.

### Technical Solution

According to an aspect of the present invention, there is provided a method of forming a silicon nitride used as a charge accumulation layer of a semiconductor memory device, the method including performing plasma CVD by using processing gases comprising a nitrogen gas and a gas of a compound formed of silicon atoms and chlorine atoms, and by setting a pressure in a processing container within a range between more than or equal to 0.1 Pa and less than or equal to 8 Pa, in a plasma CVD apparatus that performs film-formation by introducing microwaves in the processing container by using a planar antenna having a plurality of holes to generate plasma.

The compound formed of silicon atoms and chlorine atoms may be tetrachlorosilane (SiCl₄) or hexachlorodisilane (Si₂Cl₆). A flow rate of a gas of tetrachlorosilane (SiCl₄) or hexachlorodisilane (Si₂Cl₆) with respect to a flow rate of all processing gases may be within a range between more than or equal to 0.03% and less than or equal to 15%.

A flow rate of the nitrogen gas with respect to a flow rate of all processing gases may be within a range between more than or equal to 5% and less than or equal to 99%.

The silicon nitride film may have a concentration of hydrogen atoms less than or equal to 9.9×10²⁰ atoms/cm³ when measured by a secondary ion mass spectroscopy (SIMS).

According to another aspect of the present invention, there is provided a method of manufacturing a semiconductor memory device obtained by forming a tunnel oxide film, a silicon nitride film constituting a charge accumulation layer, a block silicon oxide film, and a control gate electrode, on a silicon layer, wherein the silicon nitride film constituting the charge accumulation layer is formed by performing plasma CVD by using processing gases including a nitrogen gas and a gas of a compound formed of silicon atoms and chlorine atoms, and by setting a pressure in a processing container within a range between more than or equal to 0.1 Pa and less than or equal to 8 Pa, in a plasma CVD apparatus that performs film-formation by introducing microwaves in the processing container by using a planar antenna having a plurality of holes to generate plasma.

### Advantageous Effects

According to a method of forming a silicon nitride film of the present invention, a silicon nitride film having a low H amount in the film and having a lot of traps can be formed by using processing gases including a nitrogen gas and a gas of a compound formed of silicon atoms and chlorine atoms and setting a pressure in a processing container within a range more than or equal to 0.1 Pa and less than or equal to 8 Pa with respect to a plasma CVD apparatus in order to perform plasma CVD. By using the silicon nitride film as a charge accumulation layer, a semiconductor memory device having an excellent data writing characteristic and an excellent data holding characteristic can be provided.

### BRIEF DESCRIPTION OF THE DRAWINGS

FIG. 1 is a schematic cross-sectional view showing an example of a plasma CVD apparatus suitable for forming a silicon nitride film;

FIG. 2 is a diagram of a structure of a planar antenna;

FIG. 3 is a diagram for explaining a structure of a control unit;

FIG. 4 is diagrams showing an example of processes of a method of forming a silicon nitride film of the present invention;

FIG. 5 is graphs showing results of SIMS measurement;

FIG. 6 is graphs showing results of FT-IR measurement;

FIG. 7 is a structural diagram of a test device having a SONOS structure;

FIG. 8 is a graph showing test results of dependence of a writing characteristic on a species of a material gas;

FIG. 9 is a graph showing test results of dependence of a data holding characteristic on a species of a material gas;

FIG. 10 is a graph showing test results of an effect of a pre-coating film on a data holding characteristic;

FIG. 11 is a graph showing a relationship between a data holding characteristic and a hydrogen amount in a film;

FIG. 12 is a graph showing test results of dependence of a data writing characteristic on a film-forming pressure;

FIG. 13 is a structural diagram of a test device having a TANOS structure;

FIG. 14 is graphs showing results of reliability tests;

FIG. 15 is a graph showing a relationship between a process pressure of plasma CVD and a refractive index of a silicon nitride film;

FIG. 16 is a graph showing a relationship between microwave power of plasma CVD and a refractive index of a silicon nitride film;

FIG. 17 is a graph showing a relationship between a N₂ flow rate of plasma CVD and a refractive index of a silicon nitride film; and

FIG. 18 is a diagram showing a schematic configuration of a semiconductor memory device to which a method of the present invention is applicable.

### EXPLANATION ON REFERENCE NUMERALS

1: Processing Container

2: Holding Stage

3: Supporting Member

5: Heater

12: Exhaust Pipe

14: Gas Introduction Unit

14a: First Gas Introduction Unit

14b: Second Gas Introduction Unit

16: Inlet/Outlet

17: Gate Valve

18: Gas Supplying Apparatus

19a: Nitrogen Gas Supply Source

19b: Si-containing Gas Supply Source

19c: Inert Gas Supply Source

19d: Cleaning Gas Supply Source

24: Exhaust Apparatus

27: Microwave Introduction Mechanism

28: Transmission plate

29: Seal Member

31: Planar Antenna

32: Microwave Radiation Hole

37: Waveguide

39: Microwave Generator

50: Control Unit

100: Plasma CVD Apparatus

W: Semiconductor Wafer (Substrate)

### BEST MODE FOR CARRYING OUT THE INVENTION

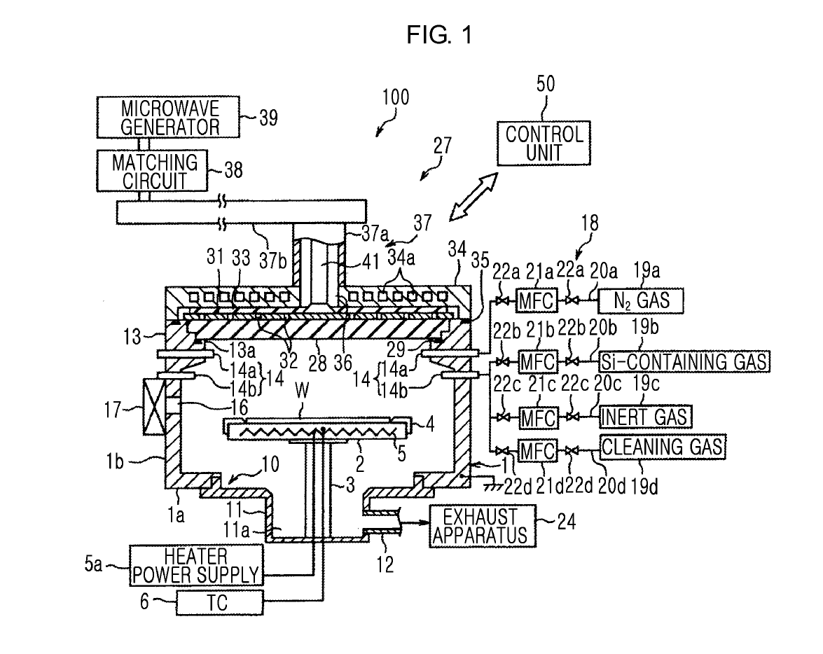

Hereinafter, the present invention will be described in detail by explaining exemplary embodiments of the invention with reference to the attached drawings. FIG. 1 is a schematic cross-sectional view showing a schematic structure of a plasma CVD apparatus 100 used in forming a silicon nitride film of the present invention.

The plasma CVD apparatus 100 is configured as an RLSA (Radial Line Slot Antenna) microwave plasma processing apparatus that can generate microwave excitation plasma having a high density and a low electron temperature, by generating plasma by introducing microwaves into a process chamber by using a planar antenna having a plurality of slots, specifically, an RLSA. The plasma CVD apparatus 100 is able to perform a process using plasma having a low electron temperature from 0.7 eV to 2 eV, and a plasma density from 1×10¹⁰/cm³ to 5×10¹²/cm³. Accordingly, the plasma CVD apparatus 100 may be very suitably used for a purpose of forming a silicon nitride film by using plasma CVD while manufacturing various semiconductor devices.

The plasma CVD apparatus 100 mainly include an airtight processing container 1, a gas supplying apparatus 18 for supplying a gas into the processing container 1, a gas introduction unit 14 connected to the gas supplying apparatus 18, an exhaust apparatus 24 constituting an exhaust mechanism for depressurizing and exhausting an inside of the processing container 1, a microwave introduction mechanism 27 disposed above the processing container 1 and for introducing microwaves into the processing container 1, and a control unit 50 for controlling each element of the plasma CVD apparatus 100. Alternatively, the gas supplying apparatus 18 may not be included as an element of the plasma CVD apparatus 100, and an external gas supplying apparatus may be used by being connected to the gas introduction unit 14.

The processing container 1 is a grounded container having an approximately cylindrical shape. Alternatively, the processing container 1 may be a container having a prismatic shape. The processing container 1 has a bottom wall 1a and a side wall 1b that are formed of a material such as aluminum.

A holding stage 2 for horizontally supporting a semiconductor wafer (hereinafter, simply referred to as a “wafer”) W constituting an object to be processed is provided inside the processing container 1. The holding stage 2 is formed of a material having a high thermal conductivity, for example, ceramic such as AlN. The holding stage 2 is supported by a supporting member 3 having a cylindrical shape extending upward from a bottom center of an exhaust room 11. The supporting member 3 may be formed of ceramic such as AlN.

A cover ring 4 for covering an outer circumferential portion of the holding stage 2 and guiding the wafer W is provided on the holding stage 2. The cover ring 4 is a ring-shaped member formed of a material such as quartz, AlN, Al₂O₃, or SiN.

A resistance heating type heater 5 is buried in the holding stage 2, to serve as a temperature adjusting mechanism. The heater 5 heats the holding stage 2 by receiving power from a heater power supply 5a, and the wafer W constituting a substrate to be processed is uniformly heated by heat from the holding stage 2.

A thermocouple (TC) 6 is disposed at the holding stage 2. A temperature is measured by using the thermocouple 6, and thus a heating temperature of the wafer W is controllable, for example, in a range from room temperature to 900° C.

Also, the holding stage 2 includes wafer support pins (not shown) for supporting and elevating the wafer W. Each wafer support pin is provided to be able to protrude and retract with respect to a surface of the holding stage 2.

A circular opening 10 is formed around a center of the bottom wall 1a of the processing container 1. The exhaust room 11, which protrudes downward from the bottom wall 1a and communicates with the opening 10, is provided on the bottom wall 1a. The exhaust room 11 is connected to an exhaust pipe 12, and is connected to the exhaust apparatus 24 through the exhaust pipe 12.

A plate 13 serving as a lid for opening and closing the processing container 1 is disposed on an upper end of the side wall 1b forming the processing container 1. The plate 13 has an opening therein, and an inner circumference of the plate 13 protrudes inward (toward a space inside the processing container) to form a ring-shaped supporter 13a.

An annular first gas introduction unit 14a having a first gas introduction hole is provided at the plate 13. Also, an annular second gas introduction unit 14b having a second gas introduction hole is provided at the side wall 1b of the processing container 1. In other words, the first and second gas introduction units 14a and 14b are provided in two stages to constitute the gas introduction unit 14. Each of the first and second gas introduction units 14a and 14b is connected to the gas supplying apparatus 18 for supplying a processing gas. Alternatively, the first and second gas introduction units 14a and 14b may each have a nozzle shape or a shower head shape. Alternatively, the first and second gas introduction units 14a and 14b may be provided as a single shower head.

An inlet/outlet 16 for transferring the wafer W between the plasma CVD apparatus 100 and a transfer room (not shown) adjacent to the plasma CVD apparatus 100, and a gate valve 17 for opening and closing the inlet/outlet 16 are provided at the side wall 1b of the processing container 1.

The gas supplying apparatus 18 includes gas supply sources (for example, a nitrogen gas supply source 19a, a silicon (Si) containing gas supply source 19b, an inert gas supply source 19c, and a cleaning gas supply source 19d), pipes (for example, gas lines 20a, 20b, 20c, and 20d), flow rate control apparatuses (for example, mass flow controllers 21a, 21b, 21c, and 21d), and valves (for example, opening/shutting valves 22a, 22b, 22c, and 22d). The nitrogen gas supply source 19a is connected to the first gas introduction unit 14a located at an upper stage. Also, the Si-containing gas supply source 19b, the inert gas supply source 19c, and the cleaning gas supply source 19d are connected to the second gas introduction unit 14b located at a lower stage. The cleaning gas supply source 19d is used to clean unnecessary films adhered inside the processing container 1. Also, the gas supplying apparatus 18 includes, for example, a purge gas supply source used to replace an atmosphere inside the processing container 1, as another gas supply source (not shown).

In the present invention, a gas of a compound formed of silicon atoms and chlorine atoms, for example, SiₙCl₂ₙ₊₂, such as tetrachlorosilane (SiCl₄) or hexachlorosilane (Si₂Cl₆), is used as a silicon (Si) containing gas. Also, a nitrogen (N₂) gas is used together with the silicon (Si) containing gas as a film-forming material. Since SiCl₄, Si₂Cl₆, and N₂ do not contain hydrogen in material gas molecules, they may be preferably used in the present invention. Also, for example, a rare gas may be used as an inert gas. The rare gas helps generation of stable plasma, as a plasma excitation gas, and for example, an Ar gas, a Kr gas, an Xe gas, or an He gas, may be used as the rare gas. Specifically, an Ar gas is preferable in terms of expenses and an industrial aspect.

An N₂ gas reaches the first gas introduction unit 14a from the nitrogen gas supply source 19a of the gas supplying apparatus 18 through the gas line 20a, and is introduced into the processing container 1 from a gas introduction hole (not shown) of the first gas introduction unit 14a. Meanwhile, the Si-containing gas, the inert gas, and a cleaning gas reach the second gas introduction unit 14b respectively from the Si-containing gas supply source 19b, the inert gas supply source 19c, and the cleaning gas supply source 19d respectively through the gas lines 20b, 20c, and 20d, and are introduced into the processing container 1 from a gas introduction hole (not shown) of the second gas introduction unit 14b. The mass flow controllers 21a through 21d and the opening/shutting valves 22a through 22d respectively in front of and behind the mass flow controllers 21a through 21d are respectively provided in the gas lines 20a through 20d respectively connected to the gas supply sources. Switching, a flow rate, and the like of a supplied gas are controllable by such a configuration of the gas supplying apparatus 18. Here, the rare gas for plasma excitation, such as an Ar gas, is an optional gas, and does not have to be supplied at the same time as with a film-forming material gas (Si-containing or an N₂ gas), but may be added in order to is stabilize plasma. Particularly, an Ar gas may be used as a carrier gas for stably supplying a SiCl₄ gas into the processing container.

The exhaust apparatus 24 includes a vacuum pump (not shown), such as a turbomolecular pump. As described above, the exhaust apparatus 24 is connected to the exhaust pipe 12, and the exhaust pipe 12 is connected to the exhaust room 11 of the processing container 1. By operating the exhaust apparatus 24, a gas inside the processing container 1 uniformly flows inside a space 11a of the exhaust room 11, and is then externally exhausted from the space 11a through the exhaust pipe 12. Accordingly, it is possible to depressurize the inside of the processing container 1, for example, up to 0.133 Pa, at a high speed.

A configuration of the microwave introduction mechanism 27 will now be described. The microwave introduction mechanism 27 mainly includes a transmission plate 28, a planar antenna 31, a wavelength-shortening member 33, a cover 34, a waveguide 37, and a microwave generator 39.

The transmission plate 28 through which microwaves are transmitted is arranged on the supporter 13a protruding from an inner circumference of the plate 13. The transmission plate 28 is formed of a dielectric, for example, ceramic such as quartz, Al₂O₃, or AlN. A space between the transmission plate 28 and the supporter 13a is sealed airtightly by disposing a seal member 29. Accordingly, the processing container 1 is held airtightly.

The planar antenna 31 is provided above the transmission plate 28 to face the holding stage 2. The planar antenna 31 has a disk shape. However, the shape of the planar antenna 31 is not limited to the disk shape, and the planar antenna 31 may have a rectangular plate shape. The planar antenna 31 is engaged to a top end of the plate 13.

The planar antenna 31 is formed of, for example, a copper plate, a nickel plate, an SUS plate, or an aluminum plate, having surfaces coated with gold or silver. The planar antenna 31 includes a plurality of microwave radiation holes 32 for radiating microwaves each having a slot shape. The microwave radiation holes 32 penetrate is through the planar antenna 31 in a predetermined pattern.

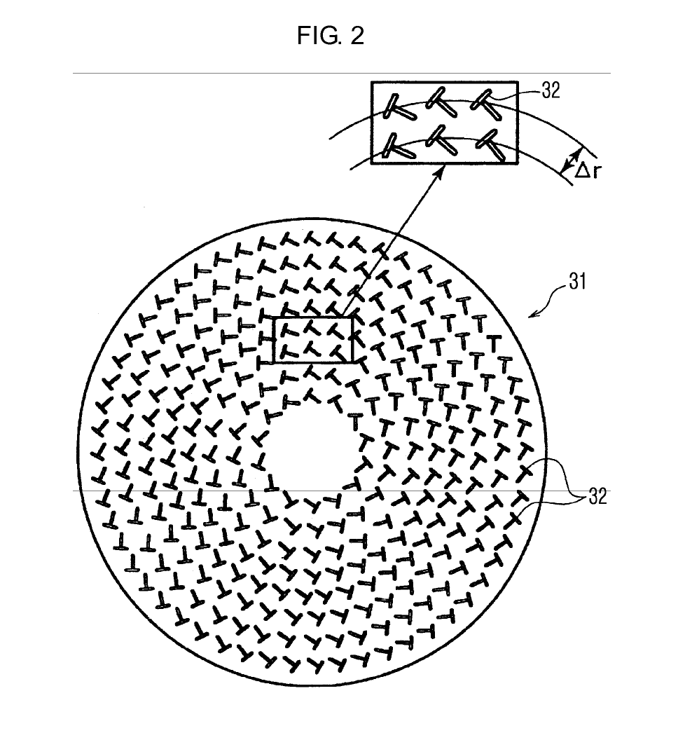

Each microwave radiation hole 32 has, for example, a thin and long rectangular shape (slot shape) as shown in FIG. 2, and two adjacent microwave radiation holes form a pair. The adjacent microwave radiation holes 32 are typically disposed in an “L” or “V” shape. Also, overall, the microwave radiation holes 32 disposed after combining in such a predetermined shape are also arranged in a concentric shape.

Lengths or arrangement intervals of the microwave radiation holes 32 are determined according to a wavelength (λg) of microwaves. For example, an interval of the microwave radiation holes 32 is from

$$\frac{λ g}{4}$$

to λg. In FIG. 2, an interval between the adjacent microwave radiation holes 32 arranged in a concentric shape is Δr. Alternatively, a shape of each microwave radiation hole 32 may vary and be, for example, a circular shape, an arc shape, or the like. Also, a configuration of the microwave radiation holes 32 is not specifically limited, and may be, for example, a spiral shape or a radial shape, aside from the concentric shape.

The wavelength-shortening material 33, having a dielectric constant higher than vacuum, is provided on a top surface of the planar antenna 31. The wavelength-shortening material 33 shortens a wavelength of microwaves in order to adjust plasma, since the wavelength of the microwaves lengthens in a vacuum.

Also, the planar antenna 31 and the transmission plate 28, and the wavelength-shortening material 33 and the planar antenna 31 may contact or be separated from each other, but preferably contact each other.

The cover 34 may be provided on a top portion of the processing container 1 so as to cover the planar antenna 31 and the wavelength-shortening material 33. The cover 34 may be formed of, for example, a metal material such as aluminum or stainless steel. A seal member 35 seals between a top end of the plate 13 and the cover 34. A cooling water passage 34a may be formed inside the cover 34. Cooling water flows through the cooling water path 34a, thereby cooling the cover 34, the wavelength-shortening material 33, the planar antenna 31, and the transmission plate 28. Also, the cover 34 is grounded.

An opening 36 is formed on a center of a top wall (ceiling portion) of the cover 34, and the waveguide 37 is connected to the opening 36. Another end of the waveguide 37 is connected to the microwave generator 39 for generating microwaves, through a matching circuit 38.

The waveguide 37 includes a coaxial waveguide 37a having a circular cross-section and extending upward from the opening 36 of the cover 34, and a rectangular waveguide 37b connected to an upper end of the coaxial waveguide 37a and extending in a horizontal direction.

An inner conductor 41 extends in a center of the coaxial waveguide 37a. A lower end portion of the inner conductor 41 is connected and fixed to a center of the planar antenna 31. According to such a structure, microwaves are efficiently uniformly propagated in a radial shape to the planar antenna 31 through the inner conductor 41 of the coaxial waveguide 37a.

By using the microwave introduction mechanism 27 having the above configuration, microwaves generated in the microwave generator 39 are propagated to the planar antenna 31 through the waveguide 37, and then are introduced into the processing container 1 through the transmission plate 28. Also, a frequency of the microwaves may be, for example, 2.45 GHz, and may be 8.35 GHz, 1.98 GHz, or the like.

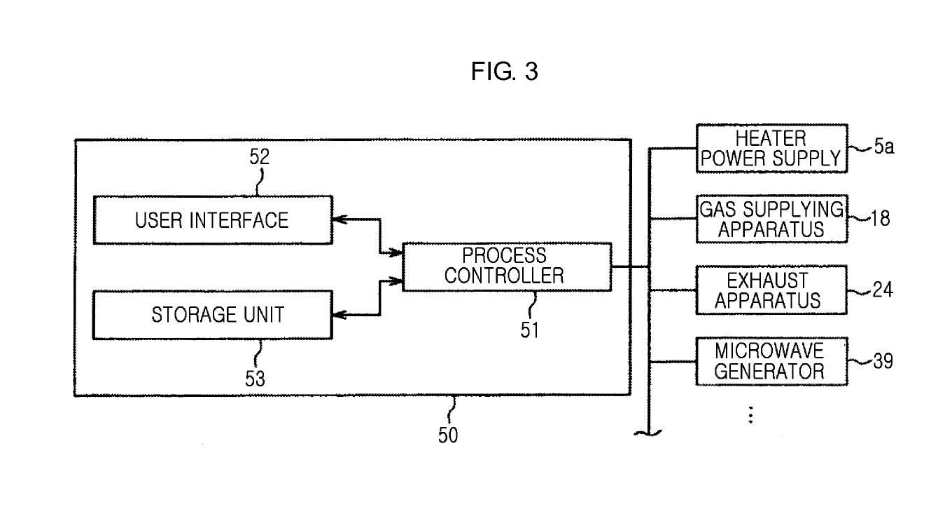

Each element of the plasma CVD apparatus 100 is connected to and controlled by the control unit 50. The control unit 50 includes a computer, and, for example, includes a process controller 51 having a CPU, and a user interface 52 and a storage unit 53 connected to the process controller 51, as shown in FIG. 3. The process controller 51 is a control unit that generally controls elements of the plasma CVD apparatus 100 that are related to process conditions, such as a temperature, a pressure, a gas flow rate, and a microwave output power (for example, the heater power supply 5a, the gas supplying apparatus 18, the exhaust apparatus 24, and the microwave generator 39).

The user interface 52 includes a keyboard for an operation manager to perform input manipulation or the like of a command to manage the plasma CVD apparatus 100, a display for visually displaying an operation situation of the plasma CVD apparatus 100, and the like. Also, the storage unit 53 stores a control program (software) for executing various processes in the plasma CVD apparatus 100 under a control of the process controller 51, or a recipe on which process condition data, etc. is recorded.

Also, if required, a predetermined recipe is called from the storage unit 53 via instructions from the user interface 52 or the like and executed in the process controller 51, thereby performing a desired process in the processing container 1 of the plasma CVD apparatus 100 under a control of the process controller 51. A control program, a recipe, such as process condition data, may be stored in a computer readable recording medium, such as a CD-ROM, a hard disk, a flexible disk, a flash memory, a DVD, a Blu-ray disk, or the like, and accessed therefrom, or may be frequently received from another device, for example, online through an exclusive line.

Next, a deposition process of a silicon nitride film using a plasma CVD method using the RLSA type plasma CVD apparatus 100 will be described. First, the gate valve 17 is opened and the wafer W is transferred into the processing container 1 through the inlet/outlet 16 and held and heated on the holding stage 2. Then, while depressurizing and exhausting the inside of the processing container 1, for example, a nitrogen gas, an SiCl₄ gas, and, if required, an Ar gas are introduced into the processing container 1 respectively from the nitrogen gas supply source 19a, the Si-containing gas supply source 19b, and the inert gas supply source 19c of the gas supplying apparatus 18 respectively through the first and second gas introduction units 14a and 14b, at predetermined flow rates. Also, the inside of the processing container 1 is set to a predetermined pressure. Conditions at this time will be described later.

Then, microwaves of a predetermined frequency, for example, 2.45 GHz, generated in the microwave generator 39 are induced to the waveguide 37 through the matching circuit 38. The microwaves induced to the waveguide 37 sequentially pass through the rectangular waveguide 37b and the coaxial waveguide 37a, and are is supplied to the planar antenna 31 through the inner conductor 41. The microwaves are propagated in a radial shape from the coaxial waveguide 37a toward the planar antenna 31. Also, the microwaves are radiated to a space above the wafer W in the processing container 1 from the microwave radiation holes 32 each having a slot shape of the planar antenna 31 through the transmission plate 28.

An electromagnetic field is formed inside the processing container 1 due to the microwaves radiated to the processing container 1 from the planar antenna 31 through the transmission plate 28, and thus the nitrogen gas, the SiCl₄ gas, and the Ar gas are each plasmatized. Then, material gases are efficiently dissociated in the plasma, and a thin film of silicon nitride (SiN film; here, a composition ratio of Si and N is not definitely determined stoichiometrically, but has different values according to film-forming conditions. The same is applied hereinafter) is deposited according to a reaction of active species of SiCl₃, N, etc. (ions, radicals, etc.).

The above conditions are stored as a recipe in the storage unit 53 of the control unit 50. Also, the process controller 51 reads the recipe, and transmits a control signal to each element of the plasma CVD apparatus 100, for example, the heater power supply 5a, the gas supplying apparatus 18, the exhaust apparatus 24, and the microwave generator 39, thereby realizing a plasma CVD process performed under a desired condition.

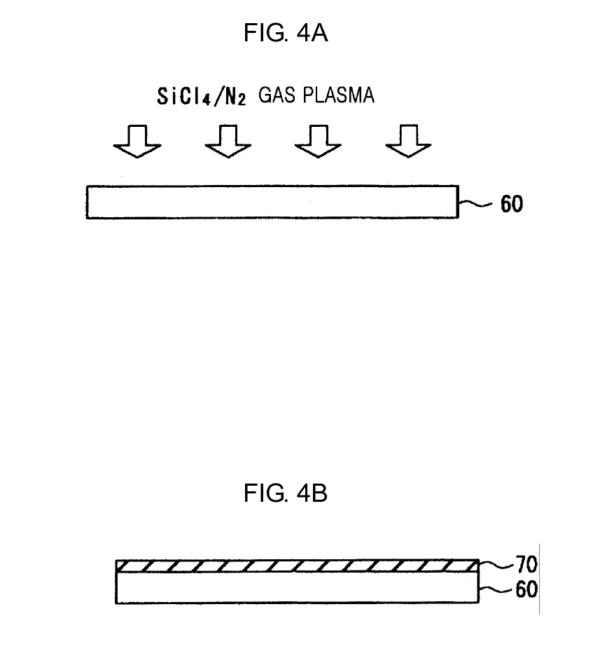

FIG. 4 is process diagrams showing processes of forming a silicon nitride film that are performed by the plasma CVD apparatus 100. As shown in FIG. 4(a), a plasma CVD process using, for example, SiCl₄/N₂ gas plasma, is performed on a predetermined base layer (for example, an SiO₂ film 60) by using the plasma CVD apparatus 100. The plasma CVD process is performed under following conditions by using a film-forming gas including the SiCl₄ gas and the nitrogen gas. Also, following descriptions use SiCl₄, but the following conditions may be equally applied when SiₙCl₂ₙ₊₂, such as Si₂Cl₆, is used as an Si-containing gas.

A process pressure may be set in a range between more than or equal to 0.1 Pa and less than or equal to 8 Pa, preferably in a range between more than or equal to 0.1 Pa and less than or equal to 6.5 Pa, and more preferably in a range between more than or equal to 0.1 Pa and less than or equal to 5.5 Pa. The lower the process pressure, the better, and the lowest limit 0.1 Pa of the range is set based on a restriction of an apparatus (limitation of a high vacuum level). When the process pressure exceeds 8 Pa, the SiCl₄ gas does not dissociate, and thus a film may not be sufficiently formed.

Also, a ratio of a flow rate of the SiCl₄ gas to a flow rate of all process gases (a percentage of

$$\frac{flow rate of {SiCl}_{4} gas}{flow rate of all process gases} )$$

may be more than or equal to 0.03% and less than or equal to 15%, and preferably more than or equal to 0.03% and less than or equal to 1%. Also, the flow rate of the SiCl₄ gas may be set to be more than or equal to 0.5 mL/min (sccm) and less than or equal 10 mL/min (sccm), and preferably more than or equal to 0.5 mL/min (sccm) and less than or equal to 2 mL/min (sccm).

Also, a ratio of a flow rate of the nitrogen gas to the flow rate of the all process gases (for example, a percentage of

$$\frac{flow rate of {N}_{2} gas}{flow rate of all process gases} )$$

may be more than or equal to 5% and less than or equal to 99%, and preferably more than or equal to 40% and less than or equal to 99%. Also, the flow rate of the nitrogen gas may be set to be more than or equal to 100 mL/min (sccm) and less than or equal to 1000 mL/min (sccm), and preferably more than or equal to 300 mL/min (sccm) and less than or equal to 600 mL/min (sccm).

Also, a ratio of a flow rate of the Ar gas to the flow rate of the all process gases for example, a percentage of

$$\frac{flow rate of Ar gas}{flow rate of all process gases} )$$

may be more than or equal to 0 and less than or equal to 90%, and preferably more than or equal to 0 and less than or equal to 60%. Also, the flow rate of the inert gas may be set to be more than or equal to 0 mL/min (sccm) and less than or equal to 1000 mL/min (sccm), and preferably more than or equal to 0 mL/min (sccm) and less than or equal to 200 mL/min (sccm).

Also, a temperature of the plasma CVD process may be set to be such that a temperature of the holding stage 2 is more than or equal to 300° C., and preferably more than or equal to 400° C. and less than or equal to 600° C.

Also, a microwave output power in the plasma CVD apparatus 100 as may be such that a power density per area of the transmission plate 28 is in a range from 0.25 W/cm² to 2.56 W/cm². The microwave output power may be selected within a range, for example, from 500 W to 5000 W, to have the power density above.

According to such plasma CVD, and as shown in FIG. 4(b), a silicon nitride film (SiN film) 70 may be deposited. The plasma CVD apparatus 100 is advantageous since the silicon nitride film 70 having a film thickness in a range, for example, from 2 nm to 300 nm, preferably from 2 nm to 50 nm, is formed with high film-forming rate by using the plasma CVD apparatus 100, and at the same time, a film-formation having a good step coverage from 80% to 100% is possible.

The silicon nitride film 70 obtained as described above contains no hydrogen atoms H originated from a material for film-formation, and has a lot of traps therein. Accordingly, for example, by using the silicon nitride film 70 as a charge accumulation layer of a semiconductor memory device, an excellent writing characteristic and an excellent data holding characteristic are obtained.

<Mechanism>

In the method of forming a silicon nitride film according to the present invention, a silicon nitride film containing substantially no hydrogen atoms H originated from a material for film-formation may be formed, and at the same time, a lot of traps may be formed in the film by using SiCl₄ and nitrogen gases as the material for film-formation. It is thought that the SiCl₄ gas used in the present invention is dissociated according to following steps from i) to iv) in plasma.

i) SiCl₄→SiCl₃+Cl

ii) SiCl₃→SiCl₂+Cl+Cl

iii) SiCl₂→SiCl+Cl+Cl+Cl

iv) SiCl→Si+Cl+Cl+Cl+Cl

(Here, Cl denotes ions)

In plasma having a high electron temperature, the dissociation reaction shown in i) to iv) may easily occur due to high energy of the plasma, and thus SiCl₄ molecules are easily separated and enter a high dissociated state. Thus, a large amount of etchant, such as Cl ions constituting active species having an etching effect, is generated from the SiCl₄ molecules, and thus a film can not be deposited. Accordingly, until now, the SiCl₄ gas has not been used as a film-forming material of plasma CVD. Accordingly, in terms of a plasma generating condition, it is preferable to form SiN through a reaction of SiCl₃ and N as a lot of SiCl₃ is generated, because free Cl ions are reduced, thereby reducing damage.

The plasma CVD apparatus 100 used in the method of the present invention is able to form plasma having a low electron temperature via a configuration of generating plasma by introducing microwaves into the processing container 1 by using the planar antenna 31 having a plurality of slots (the microwave radiation holes 32). Thus, a high dissociation state is suppressed even if the SiCl₄ gas is used as a film-forming material by controlling the process pressure and the flow rate of the processing gas to be within the above ranges by using the plasma CVD apparatus 100. In other words, dissociation of SiCl₄ molecules is suppressed in the steps of i) or ii) by plasma having a low electron temperature and low energy, thereby suppressing formation of an etchant that adversely affects film-formation. Accordingly, it is possible to form a silicon nitride film that substantially contains no hydrogen via plasma CVD using the SiCl₄ gas as a material.

Also, a reason why an excellent writing characteristic and an excellent data holding characteristic are obtained by using the silicon nitride film, which is obtained by controlling the process pressure and the flow rate of the processing gas to be within the above ranges in the plasma CVD apparatus 100 using the SiCl₄ gas and the nitrogen gas and does not substantially contain hydrogen, as a charge accumulation layer of a semiconductor memory device, is still to be explained, but a rational description is possible as follows. In other words, when a large amount of hydrogen originated from a material for film-formation is mixed into the silicon nitride film, hydrogen is detached from the film as various thermal processes are performed while manufacturing a semiconductor memory device. As a result, in response to the hydrogen that was included (is detached) in the silicon nitride film, a very shallow level is formed in the film. When the silicon nitride film having such a shallow level is used as the charge accumulation layer of the semiconductor memory device, a following effect is generated. For example, during writing, charges to be captured in a trap in the silicon nitride film are leaked through the shallow level generated due to detachment of hydrogen, and thus a writing characteristic is deteriorated. Also, during data holding, as described above, charges captured in a trap are leaked through the shallow level, and thus a data holding characteristic is deteriorated. In this behalf, when the silicon nitride film obtained by the plasma CVD apparatus 100 and that does not substantially contain hydrogen is used as a charge accumulation layer of a semiconductor memory device, a shallow level generated due to detachment of hydrogen does not exist, and thus an excellent writing characteristic and an excellent data holding characteristic may be stably obtained.

Also in the plasma CVD apparatus 100, since dissociation of a material gas for film-formation is mildly progressed by plasma having a low electron temperature, it is easy to control a deposition speed (film-forming rate) of the silicon nitride film. Accordingly, film-formation may be performed while controlling a film thickness, for example, from a thin film of about 2 nm to a relatively thick film thickness of about 300 nm.

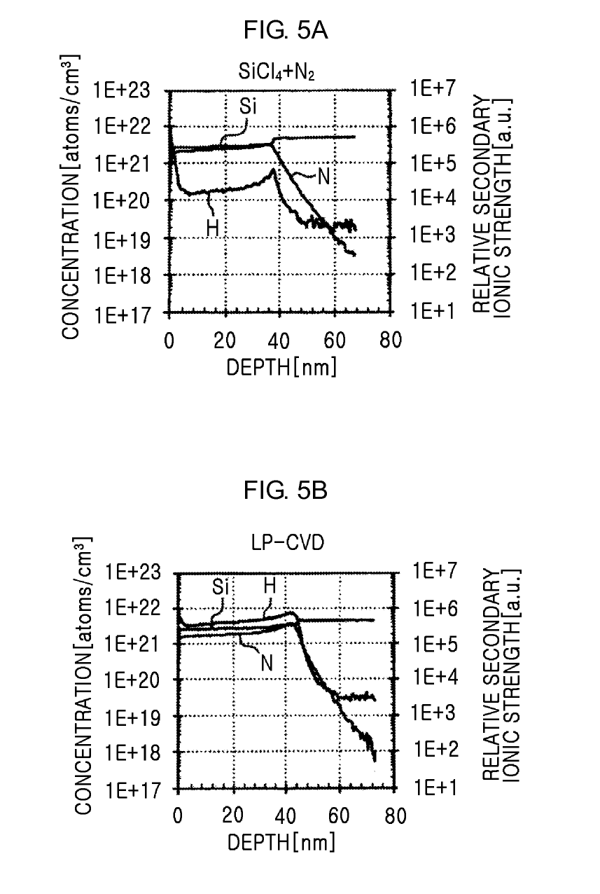

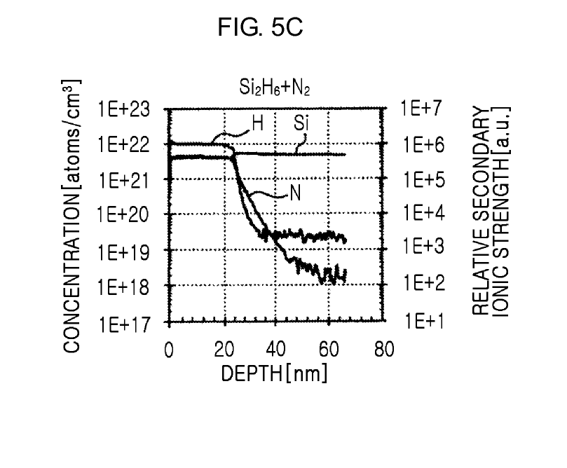

Next, descriptions of experiment data from which effects of the present invention were determined will be given. Here, in the plasma CVD apparatus 100, a silicon nitride film having a thickness of 50 nm was formed on a silicon substrate by using an SiCl₄ gas and an N₂ gas as material gases for film-formation under following conditions. A concentration of each of hydrogen, nitrogen, and silicon atoms was measured by using secondary ion mass spectrometry (RBS-SIMS), with respect to the silicon nitride film. Results thereof are shown in FIG. 5.

Also, for comparison, the same measurements were made by using SIMS with respect to a silicon nitride film formed via plasma CVD under the same conditions as those in the present invention except for using disilane (Si₂H₆) instead of SiCl₄ and with respect to a silicon nitride film formed via LPCVD (Low Pressure CVD) according to following conditions.

[Plasma CVD Conditions]

Process Temperature (Holding Stage): 400° C.

Microwave Power: 3 kW (Power Density 1.53 W/cm²; per transmission plate area)

Process Pressure: 2.7 Pa

SiCl₄ Flow Rate (or Si₂H₆ Flow Rate): 1 mL/min (sccm)

N₂ Gas Flow Rate: 450 mL/min (sccm)

Ar Gas Flow Rate: 40 mL/min (sccm)

[LPCVD Conditions]

Process Temperature: 780° C.

Process Pressure: 133 Pa

SiH₂Cl₂ Gas+NH₃ Gas: 100 mL/min (sccm)+1000 mL/min (sccm)

SIMS measurements were performed under following conditions.

Apparatus in use: ATOMIKA 4500 type (manufactured by ATOMIKA) Secondary Ion Mass Spectrometry Apparatus

First Ion Condition: Cs⁺, 1 keV, and about 20 nA

Examined Region: about 350×490 μm

Analyzed Region: about 65×92 μm

Secondary Ion Polarity: Negative (−)

Electrification Compensation: Present

Also, a hydrogen atom amount in the SIMS result is obtained by converting secondary ionic strength of H to an atom concentration by using a relative sensitivity factor (RSF) calculated by using an H concentration (6.6×10²¹ atoms/cm³) of an amount of a standard sample fixed by RBS/HR-ERDA (High Resolution Elastic Recoil Detection Analysis) (RBS-SIMS Measuring Method).

FIG. 5(a) shows a result of the measurement of a silicon nitride film formed by using SiCl₄+N₂ according to the present invention, FIG. 5(b) shows a result of the measurement of a silicon nitride film formed by using LPCVD, and FIG. 5(c) shows a result of the measurement of a silicon nitride film formed by using of Si₂H₆+N₂ as a material. Referring to FIG. 5(a), in the SiN film formed by using the method of the present invention, concentration of hydrogen atoms included in the film was 2×10²⁰ atoms/cm³, which is a detection limit level of a SIMS-RBS measuring device. Meanwhile, concentrations of hydrogen atoms included in the SiN film formed by using LPCVD and the SiN film formed by using Si₂H₆+N₂ were equal to or above 2×10²¹ atoms/cm³ and 1×10²² atoms/cm³, respectively. Based on the above results, it was determined that a level of hydrogen included in the SiN film obtained by the method of the present invention was reduced to a detection limit level, unlike the SiN films obtained by using conventional methods. In other words, according to the method of the present invention, a SiN film with hydrogen atoms below or equal to 9.9×10²⁰ atoms/cm³ may be formed.

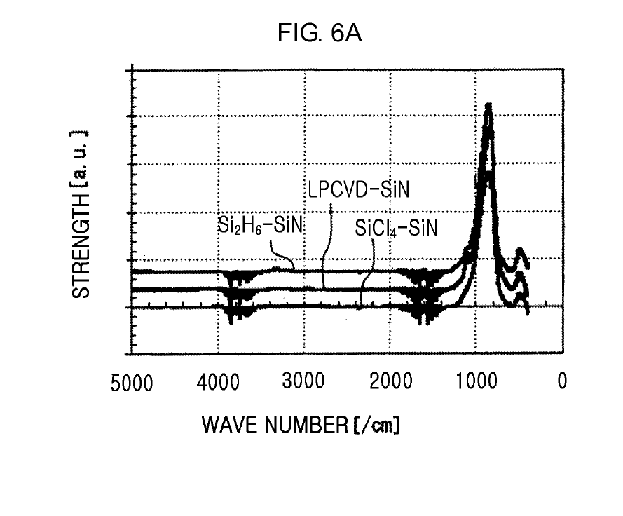

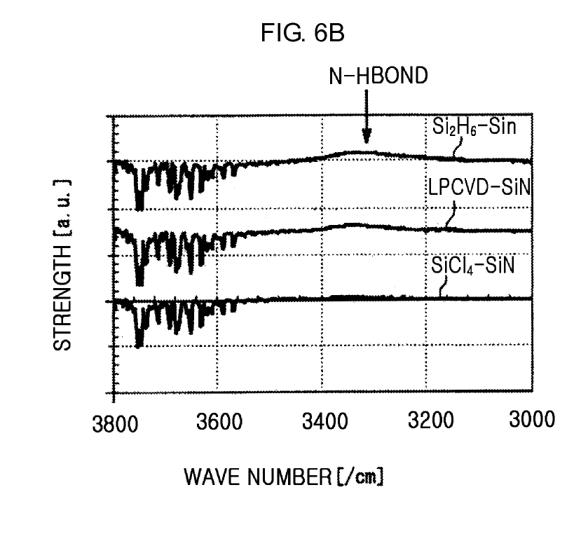

Furthermore, measurements using a Fourier transform infrared spectroscopy (FT-IR) were performed with respect to the silicon nitride film formed by using SiCl₄+N₂ as a material (the method of the present invention), the silicon nitride film formed by using LPCVD, and the silicon nitride film formed by using Si₂H₆+N₂ as a material. Results of the measurements are shown in FIGS. 6(a) and 6(b). Also, FIG. 6(b) is a magnified view of major portions of FIG. 6(a). Although peaks unique to N—H bonds were detected around a wave number of 3300 [/cm] in the cases of the silicon nitride film formed by using LPCVD and the silicon nitride film formed by using of Si₂H₆+N₂ as a material, the peak was not detected in the silicon nitride film of the present invention using SiCl₄+N₂ as a material. According to such results, it was determined that N—H bonds in the silicon nitride film using SiCl₄+N₂ as a material is equal to or below a lowest limit of detection in the FT-IR measurement.

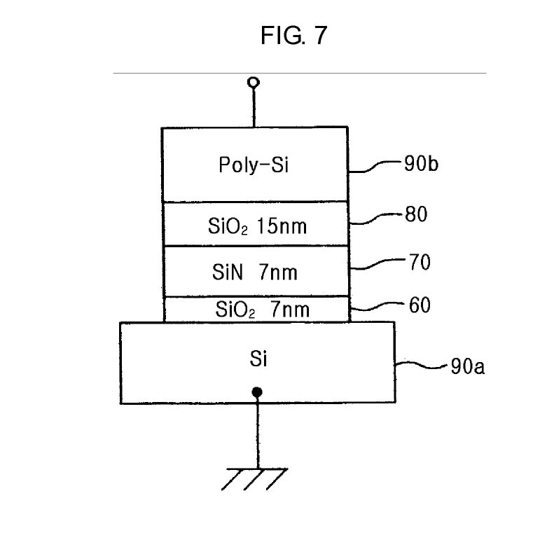

Next, an experiment was performed with respect to an electric characteristic when the silicon nitride film formed according to the method of the present invention is used as a charge accumulation layer of a semiconductor memory device. First, a test device having a SONOS structure as shown in FIG. 7 was prepared. In FIG. 7, a reference numeral 60 denotes an SiO₂ film, a reference numeral 70 denotes a silicon nitride (SiN) film, a reference numeral 80 denotes a block SiO₂ film, a reference numeral 90a denotes an Si substrate formed of single crystalline silicon, and a reference numeral 90b denotes a polycrystalline silicon film, wherein the SiN film 70 serves as a charge accumulation layer and the polycrystalline silicon film 90b serves as a control gate electrode. In this experiment, ΔVfb (Vfb hysteresis) was obtained from each CV curve (hysteresis curve) of forward and reverse by setting the silicon substrate 90a to a ground level, applying a voltage to the polycrystalline silicon film 90b by changing the voltage within a predetermined range (i.e., forward applying) then applying a voltage by changing the voltage to an opposite direction (i.e., reverse applying), and measuring capacitance during such a forward and reverse voltage applying process. Changing of a CV curve due to forward and reverse voltage application means that a voltage is changed to erase charges as holes are trapped in the SiN film 70 due to voltage application. Accordingly, the higher Vfb hysteresis is, the more excellent a writing characteristic is, because a lot of traps exist in the SiN film 70 as Vfb hysteresis is high. In the present experiment, ΔVfb was measured by applying a voltage in a range from 4 V to 6 V to the test device of FIG. 7, and a data writing characteristic was evaluated.

### EXPERIMENT EXAMPLE 1

### Evaluation of Dependence of Writing Characteristic on Material Gas Species

A silicon nitride film formed by changing a species of the Si-containing gas was used as the SiN film 70 of the test device having the SONOS structure shown in FIG. 7 to evaluate a data writing characteristic. SiCl₄, SiH₂Cl₂, or Si₂H₆ was used as the Si-containing gas. Film-forming conditions are as follows.

Plasma CVD Conditions:

The plasma CVD apparatus 100 having the configuration shown in FIG. 1 was used.

Ar Gas Flow Rate: 40 mL/min (sccm)

N₂ Gas Flow Rate: 450 mL/min (sccm)

Si-containing Gas Flow Rate: 1 mL/min (sccm)

Process Pressure: 2.7 Pa

Process Temperature (Holding Stage): 500° C.

Microwave Power: 3 kW (Output Power Density 0.25 W/cm²to 0.56 W/cm²; per transmission plate area)

Process Time: 300 seconds

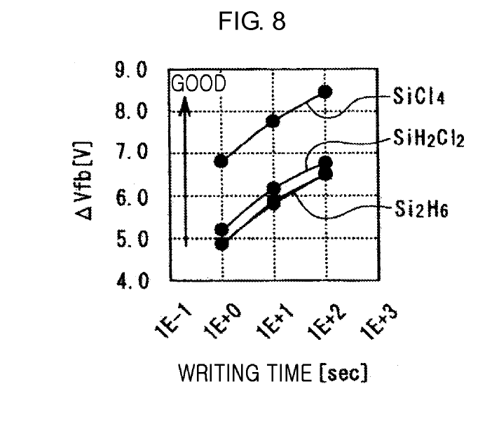

FIG. 8 shows measurement results of ΔVfb showing writing characteristics of silicon nitride films formed according to each of above conditions. Also, a horizontal axis of FIG. 8 denotes a data writing time, and 1E−n, 1E+n, etc. (where n is a number) at markings respectively denote 1×10⁻ⁿ, 1×10ⁿ, etc. (the same is applied to FIGS. 5, 12, and 14).

The writing characteristic was remarkably improved by using SiCl₄ as the Si-containing gas, compared to a case when SiH₂Cl₂ or Si₂H₆ is used. This shows that the number of traps in a film is increased when forming a film by using SiCl₄ as a precursor, compared to a case when SiH₂Cl₂ or Si₂H₆ is used as a precursor. Also, when a hydrogen amount of each silicon nitride film was measured, the hydrogen amount was 1.7×10²⁰ [atoms/cm³] when SiCl₄ was used as a precursor, 5.0×10²¹ [atoms/cm³] when SiH₂Cl₂ was used as a precursor, and 9.5×10²¹ [atoms/cm³] when Si₂H₆ was used as a precursor. In this regard, it can be checked that a hydrogen amount in a silicon nitride film and an amount of traps are related to each other, and a silicon nitride film having a very low hydrogen amount and a lot of traps can be formed as the silicon nitride film does not contain hydrogen originated from a material by using SiCl₄ and N₂, which do not contain hydrogen, as precursors.

### EXPERIMENT EXAMPLE 2

### Evaluation of Dependence of Data Holding Characteristic on Material Gas Species

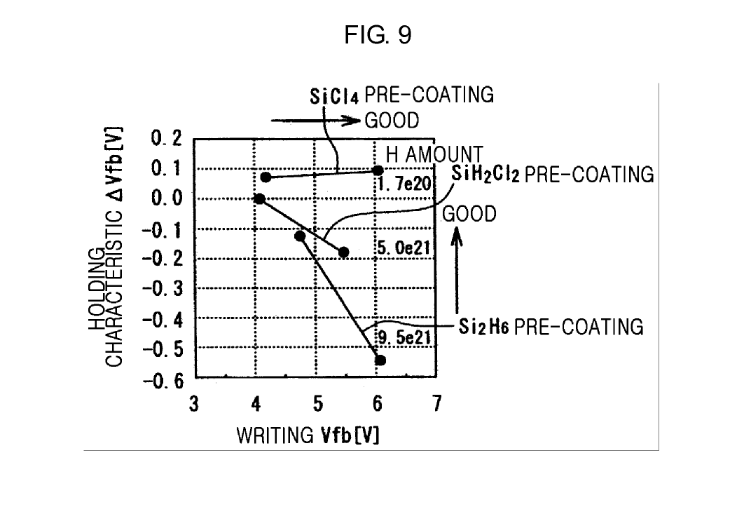

A data holding characteristic was evaluated when applying a silicon nitride film formed by using the same method as in Experiment Example 1 as the SiN film 70 of the is test device having the SONOS structure shown in FIG. 7. The data holding characteristic of the test device was measured by writing data using a voltage from 4 V to 6 V, and then measuring ΔVfb after leaving the test device for 1 hour at 300° C. The results are shown in FIG. 9.

Referring to FIG. 9, the data holding characteristic was remarkably improved when using SiCl₄ as the Si-containing gas, compared to a case when SiH₂Cl₂ or Si₂H₆ was used. This may be because a number of traps in a film increases and hydrogen originated from a material does not exist in the film, when forming a film using SiCl₄ as a precursor, compared to a case when SiCl₂H₂ or Si₂H₆ was used as a precursor.

### EXPERIMENT EXAMPLE 3

### Evaluation of Effect of Pre-coating Film on Data Holding Characteristic

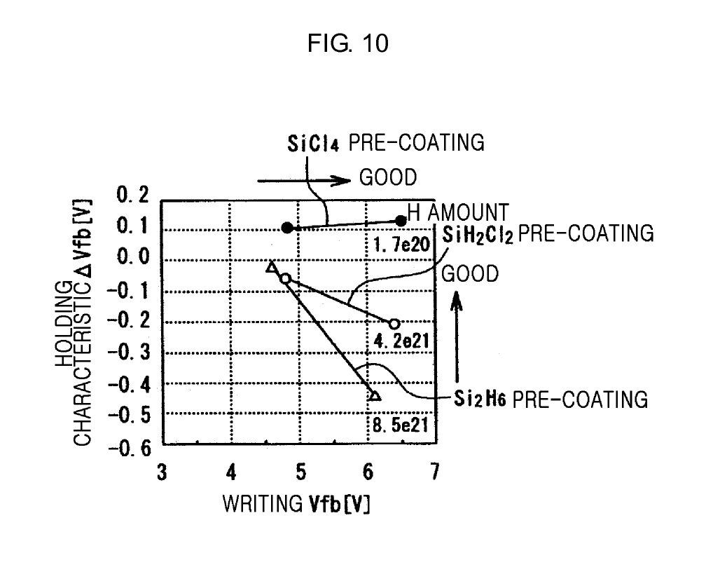

A silicon nitride film was formed by using the same method as in Experiment Example 1 by performing pre-coating in the processing container 1 of the plasma CVD apparatus 100, and then using SiCl₄ as a precursor under following conditions. SiCl₄, Si₂H₆, and SiH₂Cl₂ were used as Si-containing gases for pre-coating. The data holding characteristic was evaluated when applying the obtained silicon nitride film to the SiN film 70 of the test device having the SONOS structure shown in FIG. 7. Also, in the present experiment, the block SiO₂ film 80 was formed, and then annealing was performed under an N₂ atmosphere at 1000° C. for 60 seconds. The data holding characteristic of the test device was measured by measuring ΔVfb obtained by writing data using a voltage of 4 V to 6 V, and then leaving the test device for 1 hour at 300° C. The results are shown in FIG. 10.

Pre-coating Conditions:

Ar Gas Flow Rate: 40 mL/min (sccm)

N₂ Gas Flow Rate: 450 mL/min (sccm)

Si-containing Gas Flow Rate: 1 mL/min (sccm)

Process Pressure: 2.7 Pa

Process Temperature (Holding Stage): 500° C.

Microwave Power: 3 kW (Output Power Density 1.53 W/cm²; per transmission is plate area)

Referring to FIG. 10, it was determined that a data holding characteristic is remarkably deteriorated when Si₂H₆ is used for pre-coating, even if SiCl₄ is used as the Si-containing gas. However, an excellent data holding characteristic is shown when SiCl₄, that is, the same material as a precursor, is used for pre-coating. Also, when a hydrogen amount of each silicon nitride film was measured, the hydrogen amount was 1.7×10²⁰ [atoms/cm³] in the SiCl₄ pre-coating/SiCl₄ precursor, whereas the hydrogen amount was 4.2×10²¹ [atoms/cm³] in the SiH₂Cl₂ pre-coating/SiCl₄ precursor and was 8.5×10²¹ [atoms/cm³] in the Si₂H₆ pre-coating/SiCl₄ precursor.

### EXPERIMENT EXAMPLE 4

### Evaluation of Effect of Hydrogen Amount on Data Holding Characteristic

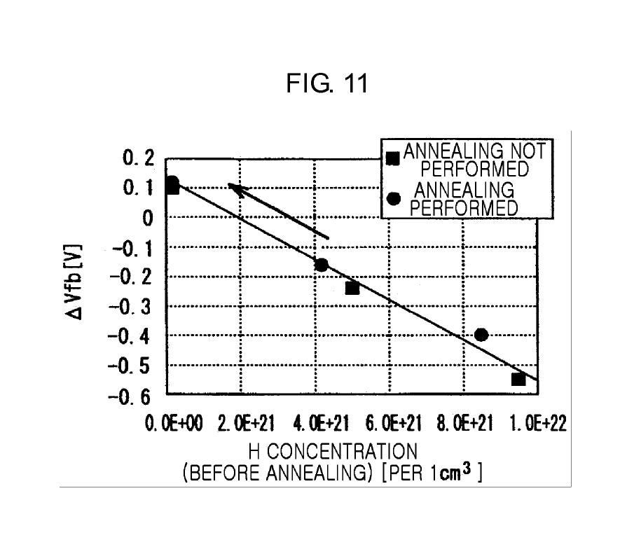

FIG. 11 shows a relationship between a data holding characteristic of a silicon nitride film formed by using the same method as in Experiment Example 1, and a hydrogen amount in the film. Also, in the present experiment, a hydrogen amount and a data holding characteristic were also measured with respect to a sample obtained by forming the block SiO₂ film 80, and then performing annealing at 1000° C. for 60 seconds, and effects of performing annealing were also evaluated.

Annealing Conditions:

Process Temperature: 1000° C.

Atmosphere: N₂

Process Time: 60 seconds

It can be determined from FIG. 11 that the data holding characteristic increases as the hydrogen amount in the silicon nitride film is decreased. Also, such a property did not change according to performing of annealing that removes hydrogen in a film. When a film is formed by using Si₂H₆ or the like constituting a precursor including hydrogen, much more hydrogen is included in a film compared to a case when a precursor such as SiCl₄, which does not include hydrogen, is used, and furthermore, based on a fact that hydrogen is not completely detached even when annealing is performed, improving of the data holding characteristic via annealing is limited. Meanwhile, the silicon nitride film obtained by using a precursor such as SiCl₄, which does not contain hydrogen, had a remarkably low hydrogen amount in a film and thus showed an excellent data holding characteristic regardless of annealing.

According to the results of Experiment Examples 1 through 4, since a lot of traps exist in the silicon nitride film, which is formed by using a precursor such as SiCl₄, not containing hydrogen, and thus which does not substantially contain hydrogen originated from a material, the silicon nitride film has an excellent data writing characteristic and an excellent data holding characteristic as a charge accumulation layer of a semiconductor memory device.

### EXPERIMENT EXAMPLE 5

### Evaluation of Dependence of Data Writing Characteristic on Film-forming Pressure

An effect of pressure when forming the silicon nitride film (SiN film) 70 was evaluated by using the test device having the same configuration as in FIG. 7 except for a film thickness. Regarding a film thickness of each film formed between the Si substrate 90a and the polycrystalline silicon film 90b (control gate electrode), the SiO₂ film 60 was 7 nm, the SiN film 70 was 8 nm, and the SiO₂ film 80 was 13 nm.

Plasma CVD Conditions:

The plasma CVD apparatus 100 having the configuration shown in FIG. 1 was used.

Ar Gas Flow Rate: 40 mL/min(sccm)

N₂ Gas Flow Rate: 400 mL/min(sccm)

SiCl₄ Gas Flow Rate: 1 mL/min(sccm)

Process Pressure: 2.7 Pa, 6.5 Pa, and 10 Pa

Process Temperature (Holding Stage): 500° C.

Microwave Power: 3 kW (Output Power Density 0.25 to 0.56 W/cm²; per transmission plate area)

Process Time: 300 seconds

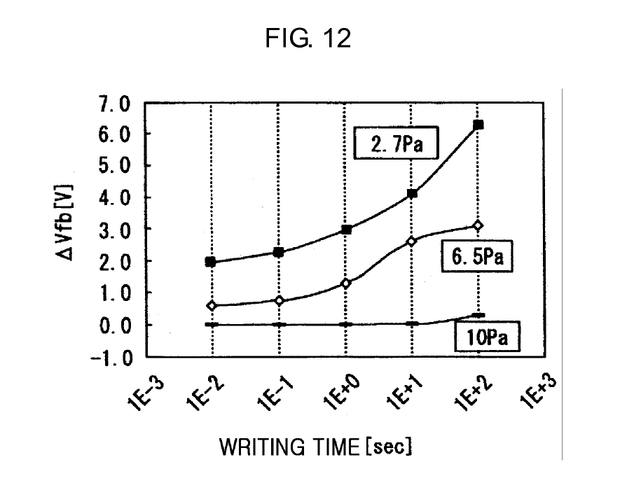

The results are shown in FIG. 12. The data writing characteristic is highest when the pressure during film-formation was 2.7 Pa, and then decreases in an order of 6.5 Pa and 10 Pa. Based on the results, it is shown that lower the process pressure the better, when a silicon nitride film is formed by using the plasma CVD apparatus 100. Accordingly, the process pressure may be, for example, in a range between more than or equal to 0.1 Pa and less than or equal to 8 Pa, preferably in a range between more than or equal to 0.1 Pa and less than or equal to 6.5 Pa, and more preferably in a range between more than or equal to 0.1 Pa and less than or equal to 5.5 Pa.

Reliability Evaluation:

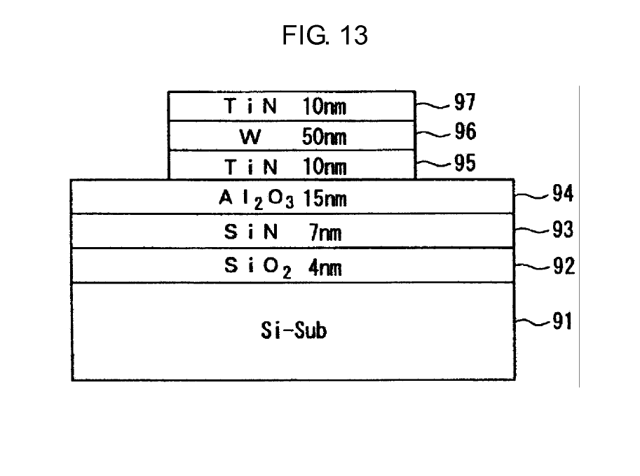

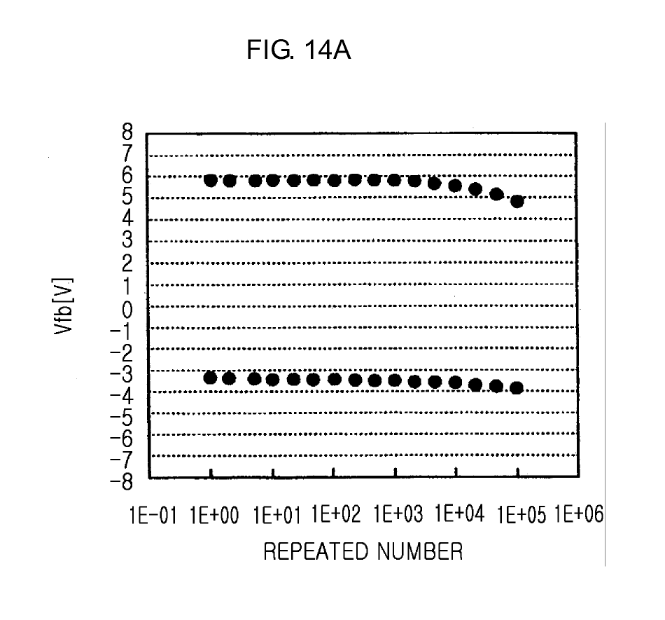

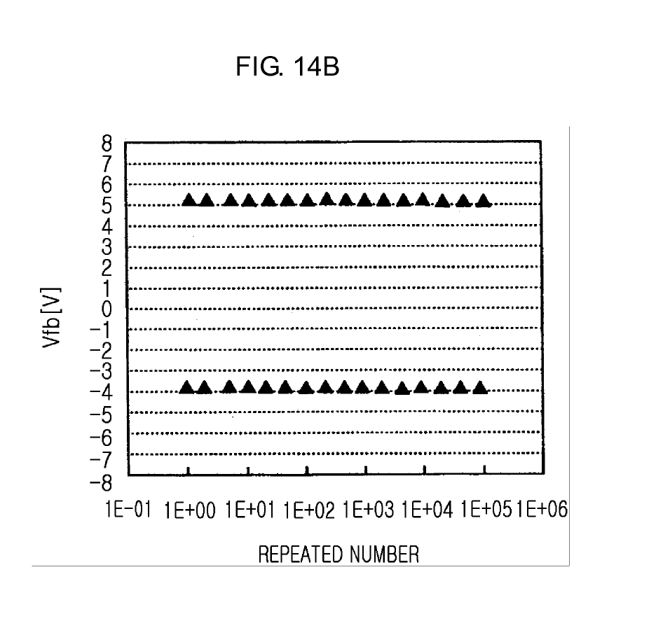

A test device of a TANOS structure (Ti/Al₂O₃/SiN/SiO₂/Si) shown in FIG. 13 was manufactured. In FIG. 13, a reference numeral 91 denotes an Si substrate, a reference numeral 92 denotes an SiO₂ film, a reference numeral 93 denotes a silicon nitride (SiN) film, a reference numeral 94 denotes an Al₂O₃ film, a reference numeral 95 denotes a TiN film, a reference numeral 96 denotes a W (tungsten) film, and a reference numeral 97 denotes a TiN film, wherein the SiN film 93 serves as a charge accumulation layer, and a stacked film of three layers of the TiN film 95, the W film 96, and the TiN film 97 serves as a control gate electrode. In this experiment, the silicon nitride film formed according to the same conditions as in Experiment Example 1 was applied to the SiN film 93, and reliability was evaluated from a change of Vfb (flat band electric potential) by repeating writing and erasing of the test device. Data writing was performed for 10 microseconds with a voltage of +16 V and data erasing was performed for 10 microseconds with a voltage of −16 V, wherein a cycle of writing and erasing was repeated about 100000 times. The results are shown in FIG. 14. FIG. 14(a) shows a result of applying a silicon nitride film formed by using Si₂H₆ including hydrogen, and N₂, as precursors, and FIG. 14(b) shows a result of applying a silicon nitride film formed by using SiCl₄ and N₂ as precursors. As shown in FIG. 14(a), in the test device using the silicon nitride film formed by using Si₂H₆ including hydrogen and constituting a precursor, Vfb of a writing characteristic deteriorated from around the 10000th time. Meanwhile, in the test device using the silicon nitride film that does not substantially include hydrogen according to the method of the present invention, Vfb barely changes even when data writing/erasing is performed 100000 times as shown in FIG. 14(b), and sufficient reliability is obtained in terms of practicality.

### EXPERIMENT EXAMPLE 6

A refractive index of a silicon nitride film formed via plasma CVD under following conditions was measured, and effects by a process pressure, microwave power, and a N₂ gas flow rate were verified.

Plasma CVD Conditions:

The plasma CVD apparatus 100 having the configuration shown in FIG. 1 was used.

Ar Gas Flow Rate: 40 mL/min (sccm)

N₂ Gas Flow Rate: 100, 300, 400, and 600 mL/min (sccm)

SiCl₄ Gas Flow Rate: 1 mL/min (sccm)

Process Pressure: 1.3 Pa, 2.7 Pa, 5 Pa, 10 Pa, and 15 Pa

Process Temperature (Holding Stage): 400° C.

Microwave Power: 1000, 2000, and 3000 W

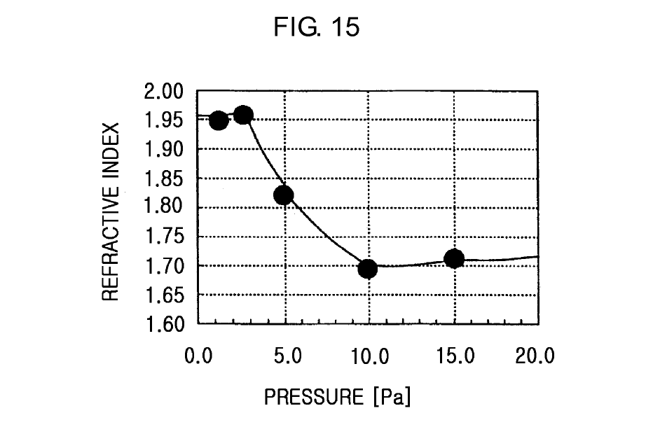

FIG. 15 shows a relationship between a process pressure of plasma CVD and a refractive index of a silicon nitride film. Based on such a result, it can be determined that the refractive index increases as the process pressure decreases. In order to obtain a silicon nitride film having a high refractive index, the process pressure may be set to less than or equal to 5 Pa.

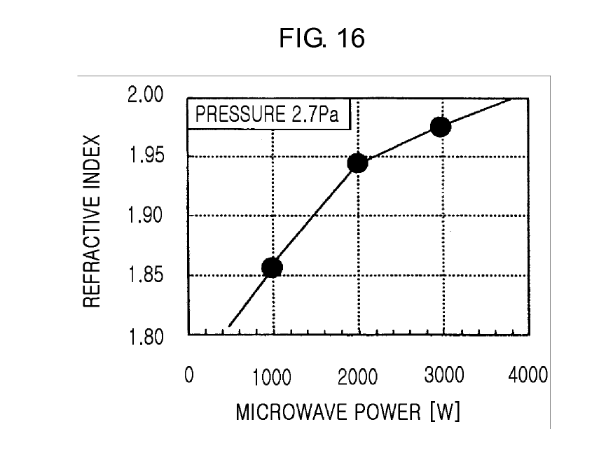

FIG. 16 shows a relationship between microwave power of plasma CVD and a refractive index of a silicon nitride film under a condition where a process pressure is 2.7 Pa. Based on such a result, it can be determined that the refractive index increases as the microwave power increases. In order to obtain a silicon nitride film having a high refractive index, a microwave output power may be, for example, from 1500 W to 5000 W.

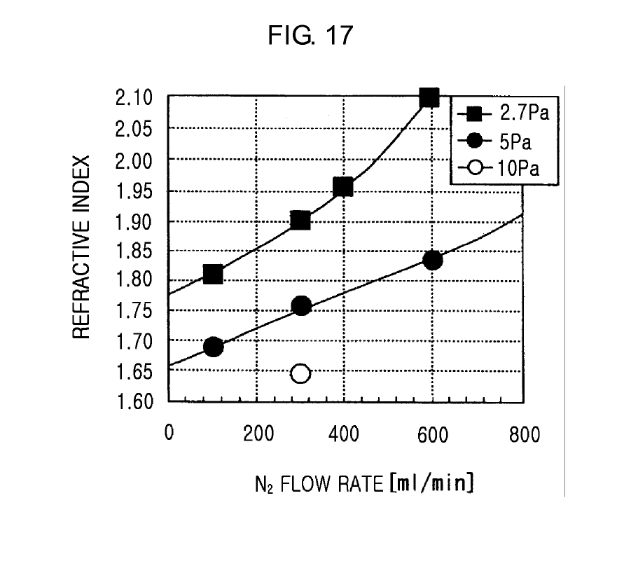

FIG. 17 shows a relationship between an N₂ flow rate of plasma CVD and a refractive index of a silicon nitride film under conditions where process pressures are 2.7 Pa, 5 Pa, and 10 Pa. Based on such a result, it can be determined that the refractive index increases as the process pressure is decreased and the N₂ flow rate is increased. In order to obtain a silicon nitride film having a high refractive index, the N₂ flow rate may be, for example, from 100 mL/min (sccm) to 1000 mL/min (sccm), and preferably from 300 mL/min (sccm) to 600 mL/min (sccm).

[Example Applied to Manufacturing of Semiconductor Memory Device]

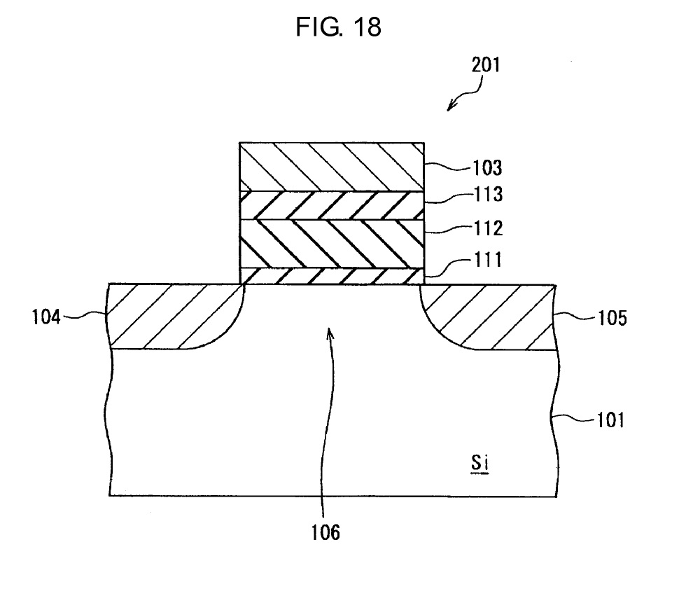

Next, an example of applying the method of fabricating a silicon nitride film according to the present embodiment to a process of manufacturing a semiconductor memory device will be described with reference to FIG. 18. FIG. 18 is a cross-sectional view of a schematic configuration of a semiconductor memory device 201. The semiconductor memory device 201 includes a p-type silicon substrate 101 constituting a semiconductor layer, a plurality of insulation films stacked on the p-type silicon substrate 101, and a gate electrode 103 additionally formed on the plurality of insulation films. A first insulation film 111, a second insulation film 112, and a third insulation film 113 are provided between the silicon substrate 101 and the gate electrode 103. Here, the second insulation film 112 is a silicon nitride film, and constitutes a charge accumulation layer in the semiconductor memory device 201.

Also, in the silicon substrate 101, first source and drain 104 and second source and drain 105, which are n-type diffusion layers, are formed to be disposed on each side of the gate electrode 103 to have a predetermined depth, and a channel forming region 106 is formed therebetween. Also, the semiconductor memory device 201 may be formed on a p-well or a p-type silicon layer formed inside a semiconductor substrate. Also, the present embodiment is explained using an n-channel MOS device as an example, but a p-channel MOS device may be used. Accordingly, descriptions of the present embodiment hereinafter may be applied both to an n-channel MOS device and a p-channel MOS device.

The first insulation film 111 is a silicon dioxide film (SiO₂ film), for example, formed by oxidizing a surface of the silicon substrate 101 by using thermal oxidation.

The second insulation film 112 is a silicon nitride film (SiN film) formed on a surface of the first insulation film 111.

The third insulation film 113 is a silicon dioxide film (SiO₂ film) deposited on the is second insulation film 112, for example, via a CVD method. The third insulation film 113 serves as a block layer (barrier layer) between the electrode 103 and the second insulation film 112.

The gate electrode 103 is, for example, formed of a polycrystalline silicon film formed by a CVD method, and serves as a control gate (CG) electrode. Alternatively, the gate electrode 103 may be a layer including a metal such as W, Ti, Ta, Cu, Al, Au, or Pt. The gate electrode 103 is not limited to have a single layer, and may have a stacked structure including, for example, tungsten, molybdenum, tantalum, titanium, platinum, a silicide thereof, a nitride thereof, an alloy thereof, etc., so as to reduce resistivity of the gate electrode 103 and increase an operating speed of the semiconductor memory device 201. The gate electrode 103 is connected to a wire layer (not shown).

Also, in the semiconductor memory device 201, most of the second insulation film 112 is a charge accumulating region that accumulates charges. Therefore, data writing performance or data holding performance of the semiconductor memory device 201 may be controlled by applying the method of forming a silicon nitride film according to the present invention and controlling a number of traps in the silicon nitride film and a distribution thereof through film-forming conditions when forming the second insulation film 112.

The example of applying the method of the present invention to the manufacturing of the semiconductor memory device 201 will be described as a representative. First, the silicon substrate 101 on which a device isolation film (not shown) is formed using a method such as a LOCOS (Local Oxidation of Silicon) method or an STI (Shallow Trench Isolation) method is prepared, and the first insulation film 111 is formed on a surface of the silicon substrate 101, for example, by using a thermal oxidation method.

Next, the second insulation film 112 is formed on the first insulation film 111 by using a plasma CVD method using the plasma CVD apparatus 100.

The second insulation film 112 may be formed such that hydrogen is prevented from entering a film and a lot of traps are formed by using a precursor such as SiCl₄, which does not contain hydrogen.

Next, the third insulation film 113 is formed on the second insulation film 112. The third insulation film 113 may be formed, for example, by using a CVD method. Also, a metal film constituting the gate electrode 103 is formed on the third insulation film 113, by forming a polysilicon layer, a metal layer such as a WSi/W, TiSi/W, polysilicon/WSi/W, WN/Cu, or Ta/Cu, a metal silicide layer, or the like by using, for example, a CVD method or a PVD method.

Then, the metal film and the third through first insulation films 113 through 111 are etched by using a patterned resist as a mask using a photolithography technology, thereby obtaining a gate stacked structure having the patterned gate electrode 103 and the plurality of insulation films. Next, a high concentration of n-type impurities are ion-injected into a silicon surface adjacent to both sides of the gate stacked structure, thereby forming the first source and drain 104 and the second source and drain 105. As such, the semiconductor memory device 201 having the structure of FIG. 18 may be manufactured.

An operation example of the semiconductor memory device 201 having such a structure is described. First, for data writing, based on electric potential of the silicon substrate 101, the first source and drain 104 and the second source and drain 105 are held to 0 V, and a predetermined positive (+) voltage is applied to the gate electrode 103. Here, an inversion layer is formed as charges are accumulated in the channel forming region 106, and a part of the charges in the inversion layer moves to the second insulation film 112 through the first insulation film 111 by a tunnel phenomenon. The charges that moved to the second insulation film 112 are trapped at a charge trapping center formed in the second insulation film 112, and data is accumulated.

For data reading, based on the electric potential of the silicon substrate 101, a voltage of 0 V is applied to any one of the first source and drain 104 and the second source and drain 105, and a predetermined voltage is applied to the other. Also, a predetermined voltage is applied to the gate electrode 103. By applying voltages as such, a current amount of a channel or a drain voltage changes according to an existence of charges accumulated in the second insulation film 112 or an amount of the accumulated charges. Accordingly, by detecting the change of the channel current or drain voltage, data may be read to outside.

For data erasing, based on the electric potential of the silicon substrate 101, a voltage of 0 V is applied to both of the first source and drain 104 and the second source and drain 105, and a negative voltage having a predetermined size is applied to the gate electrode 103. According to such application of a voltage, the charges held in the second insulation film 112 move to the channel forming region 106 of the silicon substrate 101 through the first insulation film 111. Accordingly, the semiconductor memory device 201 returns to an erased state where a charge accumulation amount in the second insulation film 112 is low.

Also, a method of writing, reading, and erasing information in the semiconductor memory device 201 is not limited, and information may be written, read, and erased by using a physical phenomenon, such as an FN tunnel phenomenon, a hot electron injection phenomenon, a hot hole injection phenomenon, or a photoelectric effect. Also, the first source and drain 104 and the second source and drain 105 may not be fixed, and may alternatively serve as a source and a drain so as to write and read information more than or equal to 2 bits, for example, 3 bits or 4 bits, in one memory cell.

Also in FIG. 18, the second insulation film 112 is used as a charge accumulation region, but the method of the present invention may be applied when a semiconductor memory device having a structure where at least two layers of a silicon nitride film are stacked as a charge accumulation layer is manufactured.

The embodiments of the present invention have been described above, but the present invention is not limited to the above embodiments, and may vary.

1. A method of forming a silicon nitride film used as a charge accumulation layer of a semiconductor memory device, the method comprising performing plasma CVD by using processing gases comprising a nitrogen gas and a gas of a compound formed of silicon atoms and chlorine atoms, and by setting a pressure in a processing container within a range between more than or equal to 0.1 Pa and less than or equal to 8 Pa, in a plasma CVD apparatus that performs film-formation by introducing microwaves in the processing container by using a planar antenna having a plurality of holes to generate plasma.

2. The method of claim 1, wherein the compound formed of silicon atoms and chlorine atoms is tetrachlorosilane (SiCl₄) or hexachlorodisilane (Si₂Cl₆).

3. The method of claim 2, wherein a flow rate of a gas of tetrachlorosilane (SiCl₄) or hexachlorodisilane (Si₂Cl₆) with respect to a flow rate of all processing gases is within a range between more than or equal to 0.03% and less than or equal to 15%.

4. The method of claim 1, wherein a flow rate of the nitrogen gas with respect to a flow rate of all processing gases is within a range between more than or equal to 5% and less than or equal to 99%.

5. The method of claim 1, wherein the silicon nitride film has a concentration of hydrogen atoms less than or equal to 9.9×10²⁰ atoms/cm³ when measured by a secondary ion mass spectroscopy (SIMS).

6. The method of claim 1, wherein the pressure in the processing container is set within a range between more than or equal to 0.1 Pa and less than or equal to 8 Pato 6.5 Pa.

7. A method of manufacturing a semiconductor memory device obtained by forming a tunnel oxide film, a silicon nitride film constituting a charge accumulation layer, a block silicon oxide film, and a control gate electrode, on a silicon layer, wherein the silicon nitride film constituting the charge accumulation layer is formed by performing plasma CVD by using processing gases including a nitrogen gas and a gas of a compound formed of silicon atoms and chlorine atoms, and by setting a pressure in a processing container within a range between more than or equal to 0.1 Pa and less than or equal to 8 Pa, in a plasma CVD apparatus that performs film-formation by introducing microwaves in the processing container by using a planar antenna having a plurality of holes to generate plasma.
